(19) United States
(12) Patent Application Publication
(10) Pub. No.: US 2011/0053307 A1
(43) Pub. Date: Mar. 3, 2011

(54) REPATTERNING OF POLYVINYL BUTYRAL SHEETS FOR USE IN SOLAR PANELS

(75) Inventors: THOMAS MCDANIEL, Sunnyvale, CA (US); Ilyoung Hong, San Jose, CA (US)

(73) Assignee: APPLIED MATERIALS, INC., Santa Clara, CA (US)

(21) Appl. No.: 12/873,783

(22) Filed: Sep. 1, 2010

Related U.S. Application Data
(60) Provisional application No. 61/239,376, filed on Sep. 2, 2009.

(51) Int. Cl. H01L 31/02; B05D 3/02; B29C 65/02; B32B 37/24

(52) U.S. Cl. 438/64; 427/372.2; 427/374.1; 427/385.5; 156/196; 156/242; 257/E31.11

(57) ABSTRACT

Embodiments of the invention provide a method of forming a composite solar cell structure that includes preparing a device substrate, wherein the device substrate includes a glass substrate, a transparent conductive layer deposited over the glass substrate, one or more silicon layers deposited over the transparent conductive layer, a back contact layer deposited over the one or more silicon layers, and one or more internal electrical connections disposed on the back contact layer. The method also includes forming a mating pattern on a bonding material to match a topography of an exposed surface of the device substrate, the exposed surface comprising the back contact layer and the one or more internal electrical connections. The method also includes positioning the bonding material over the exposed surface, disposing a back glass substrate over the bonding material to form a composite structure, and compressing the composite structure. Embodiments of the present invention also include methods of preparing a pre-patterned bonding material for a solar cell assembly.

### CROSS-REFERENCE TO RELATED APPLICATIONS

This application claims benefit of U.S. Provisional Patent Application Ser. No. 61/239,376 (APPM/014180L), filed Sep. 2, 2009, which is herein incorporated by reference. This application is related to U.S. application Ser. No. 12/202,199, filed Aug. 29, 2008 (Attorney Docket No. APPM/11141), U.S. application Ser. No. 12/201,840, filed Aug. 29, 2008 (Attorney Docket No. APPM/11141.02), and U.S. Provisional Application Ser. No. 61/149,942, filed Feb. 4, 2009 (Attorney Docket No. APPM/13847L).

### BACKGROUND OF THE INVENTION

1. Field of the Invention

Embodiments of the present invention generally relate to a method of forming solar cell devices. In particular, embodiments of the invention relate to methods of processing encapsulant layers of a solar cell device and forming solar cell devices using processed encapsulant layers.

2. Description of the Related Art

Photovoltaic (PV) devices or solar cells are devices which convert sunlight into direct current (DC) electrical power. Typical thin-film-type PV devices, or thin-film solar cells, have one or more p-i-n junctions. Each p-i-n junction comprises a p-type layer, an intrinsic-type layer, and an n-type layer. When the p-i-n junction of the solar cell is exposed to sunlight (consisting of energy from photons), the sunlight is converted to electricity through the PV effect.

Typically, a thin-film solar cell includes active regions, or photoelectric conversion units, and a transparent conductive oxide (TCO) film disposed as a front electrode and/or as a backside electrode. The photoelectric conversion unit includes a p-type silicon layer, an n-type silicon layer, and an intrinsic-type (i-type) silicon layer sandwiched between the p-type and n-type silicon layers. Several types of silicon films, including microcrystalline silicon film (μc-Si), amorphous silicon film (a-Si), polycrystalline silicon film (poly-Si), and the like, may be utilized to form the p-type, n-type, and/or i-type layers of the photoelectric conversion unit. The backside electrode may contain one or more conductive layers. There is a need for an improved process of forming a solar cell that has good interfacial contact, low contact resistance, and high overall performance.

With traditional energy source prices on the rise, there is a need for a low-cost way of producing electricity using a low-cost solar cell device. Conventional solar cell manufacturing processes are highly labor-intensive and have numerous interruptions that can affect the production line throughput, solar cell cost, and device yield. For instance, a major challenge in encapsulation of large-sized solar cells is achieving bubble-free lamination results across locally stepped topography, such as from internal electrical connections, e.g., cross- and side-buss ribbons that collect power from individual solar cells on the front glass. The large size (2.2 m×2.6 m) of substrates and the cross- and side-buss wires on the glass make the lamination process particularly sensitive to bubble formation. Bubble formation during lamination may create paths from edge to center, causing delamination or environmental encroachment, such as rain, to seep into the area and damage the solar cell.

One method to prevent bubble formation is patterning the back glass to decrease air entrapment between the encapsulant material and the back glass. Chemical etchants may be used to pattern the back glass. However, patterning the glass tends to weaken the glass substrate. Another method to prevent bubble formation is to machine encapsulant material to form a pattern. The machining process typically uses a mill to cut the pattern in the encapsulant. However, machining encapsulant tends to be expensive, very difficult, and creates a gummy final product. Therefore, there is a need for a method of decreasing bubble formation during lamination of large-size substrates used in the manufacture of solar cells along a production line having a suite of modules and improve solar cell quality.

### SUMMARY OF THE INVENTION

In one embodiment, a method of forming a composite solar cell structure includes preparing a device substrate, wherein the device substrate includes a glass substrate, a transparent conductive layer deposited over the glass substrate, one or more silicon layers deposited over the transparent conductive layer, a back contact layer deposited over the one or more silicon layers, and one or more internal electrical connections disposed on the back contact layer. The method also includes forming a mating pattern on a bonding material to match a topography of an exposed surface of the device substrate, the exposed surface comprising the back contact layer and the one or more internal electrical connections. The method also includes positioning the bonding material over the exposed surface, disposing a back glass substrate over the bonding material to form a composite structure, and compressing the composite structure.

In another embodiment, a method of preparing a pre-patterned bonding material for a solar cell assembly includes placing a bonding material over a work surface having an embossment, wherein at least a portion of the embossment corresponds to a topography of an exposed surface of a device substrate, heating the bonding material, and pressing the bonding material onto the embossment to form a mating pattern.

In another embodiment, a method of preparing a pre-patterned bonding material for a solar cell assembly, includes passing a bonding material between at least two rollers, wherein at least one roller has an embossment, at least a portion of the embossment corresponding to a topography of an exposed surface of a device substrate, heating the bonding material, and pressing the bonding material onto the embossment to form a mating pattern as the bonding material passes through the two rollers.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process sequence for forming a solar cell device according to one embodiment described herein.

FIG. 2 illustrates a plan view of a solar cell production line according to one embodiment described herein.

FIG. 3A is a side cross-sectional view of a thin-film solar cell device according to one embodiment described herein.

FIG. 3B is a side cross-sectional view of a thin-film solar cell device according to one embodiment described herein.

FIG. 3C is a plan view of a composite solar cell structure according to one embodiment described herein.

FIG. 3D is a side cross-sectional view along Section A-A of FIG. 3C.

FIG. 3E is a side cross-sectional view of a thin-film solar cell device according to one embodiment described herein.

FIG. 4 is a schematic cross-sectional view of a bonding module according to one embodiment.

FIG. 5 illustrates a side cross-sectional view of one embodiment of an autoclave module and supporting equipment.

FIG. 6A is a plane view of a composite solar cell structure without the junction box attached according to one embodiment described herein.

FIG. 6B is a close-up isometric view of the cross-buss, side-buss, and isolation tape shown on the composite solar cell structure in FIG. 6A.

FIG. 7 is a cross-sectional view of a composite solar cell structure in FIG. 6A along lines B-B.

FIG. 8 is a work surface having an embossment according to one embodiment described herein.

FIGS. 9A-9B illustrate a set of rollers having an embossment according to one embodiment described herein.

FIGS. 10A-10C illustrate a matting pattern formed on a bonding material according to embodiments described herein.

FIG. 11 is a cross-sectional view of a bonding material having a material pattern matched with the cross-buss.

FIG. 12 is a partial cross-sectional isometric view of the pre-patterned bonding material over the internal electrical connections prior to lamination.

FIG. 13 schematically illustrates a method of forming a composite solar cell structure according to one embodiment described herein.

FIG. 14 schematically illustrates a method of preparing a pre-patterned bonding material for a solar cell assembly according to one embodiment described herein.

FIG. 15 schematically illustrates a method of preparing a pre-patterned bonding material for a solar cell assembly according to one embodiment described herein.

### DETAILED DESCRIPTION

Embodiments of the invention provide a method of pre-patterning a bonding material to match a topography of an exposed surface of the device substrate. In one embodiment, the bonding material is pre-patterned before use in the formation of a solar cell by embossing a pattern that matches the topography of an exposed surface comprising a back contact layer and one or more internal electrical connections. In one embodiment, the bonding material is pressed on a work surface having an embossment that corresponds to the topography of the exposed surface. In one embodiment, the bonding material is passed between at least two rollers where at least one roller has an embossment that corresponds to the topography of the exposed surface. In one embodiment of the present invention, a method for forming a composite solar cell structure is provided.

Embodiments of the present invention generally relate to a system used to form solar cell devices using processing modules adapted to perform one or more processes in the formation of the solar cell devices. In one embodiment, the system is adapted to form thin-film solar cell devices by accepting a large unprocessed substrate, such as about 5.7 m², and performing multiple deposition, material removal, cleaning, sectioning, bonding, and various inspection and testing processes to form multiple complete, functional, and tested solar cell devices that can then be shipped to an end user for installation in a desired location to generate electricity.

While the discussion below primarily describes the formation of thin-film solar cell devices, this configuration is not intended to be limiting as to the scope of the invention since the apparatus and methods disclosed herein can also be used to form, test, and analyze other types of solar cell devices, such as III-V-type solar cells, thin-film chalcogenide solar cells (e.g., CIGS, CdTe cells), amorphous or nanocrystalline silicon solar cells, photochemical-type solar cells (e.g., dye sensitized), crystalline silicon solar cells, organic-type solar cells, or other similar solar cell devices.

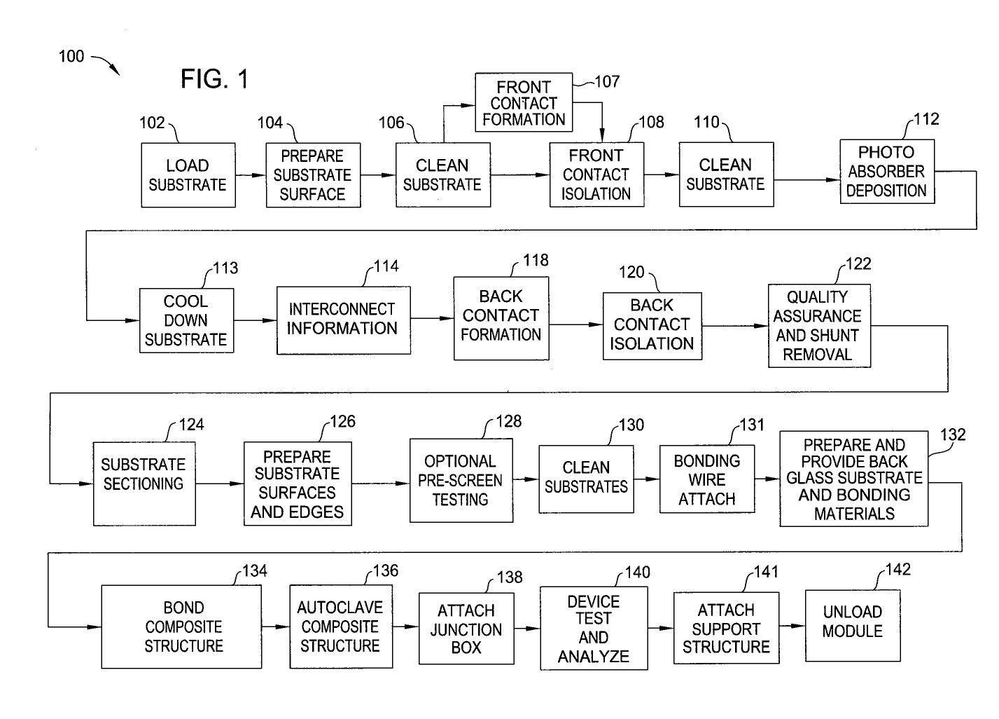

FIG. 1 illustrates one embodiment of a process sequence 100 that contains a plurality of steps (i.e., steps 102-142) that are each used to form a solar cell device using a novel solar cell production line 200 described herein. The configuration, number of processing steps, and order of the processing steps in the process sequence 100 is not intended to be limiting to the scope of the invention described herein.

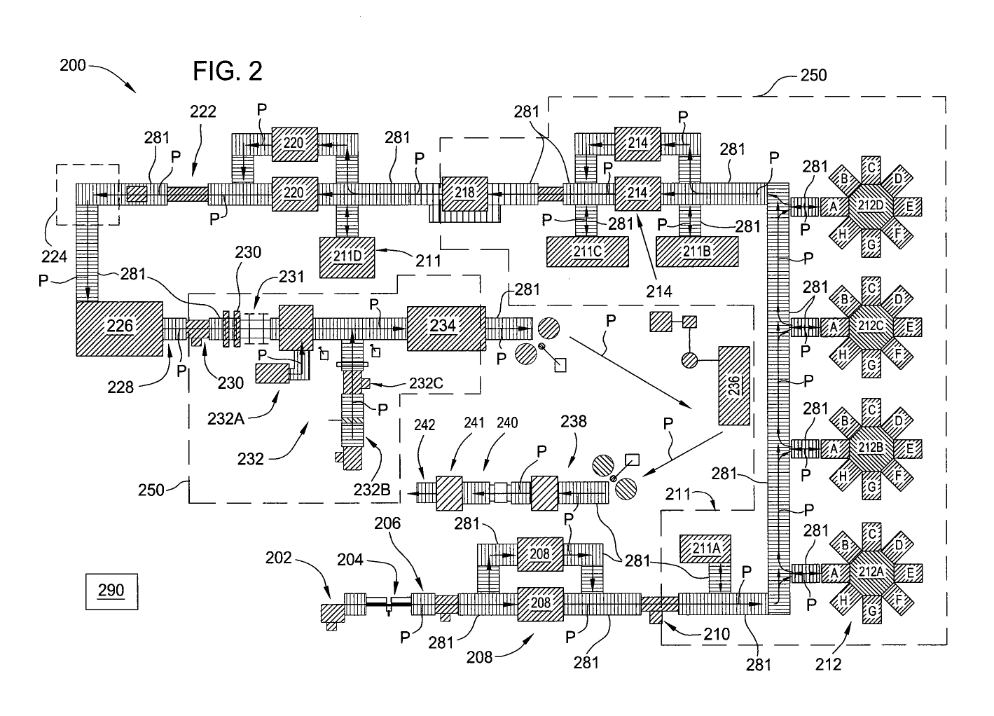

FIG. 2 is a plan view of the production line 200, which is intended to illustrate the flow of substrates through the system and other aspects of the system design. Examples and information regarding various process sequence and hardware configurations may also be found in U.S. patent application Ser. No. 12/202,199, filed Aug. 29, 2008 (Attorney Docket No. APPM/11141), U.S. patent application Ser. No. 12/201,840, filed Aug. 29, 2008 (Attorney Docket No. APPM/11141.02), and U.S. Provisional Patent Application Ser. No. 60/967,077.

In general, a system controller 290 may be used to control one or more components found in the solar cell production line 200. The system controller 290 is generally designed to facilitate the control and automation of the overall solar cell production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like.

A program (or computer instructions) readable by the system controller 290 determines which tasks are performable on a substrate. In one embodiment, the system controller 290 also contains a plurality of programmable logic controllers (PLC's) that are used to locally control one or more modules in the solar cell production, and a material handling system controller (e.g., PLC or standard computer) that deals with the higher-level strategic movement, scheduling, and running of the complete solar cell production line

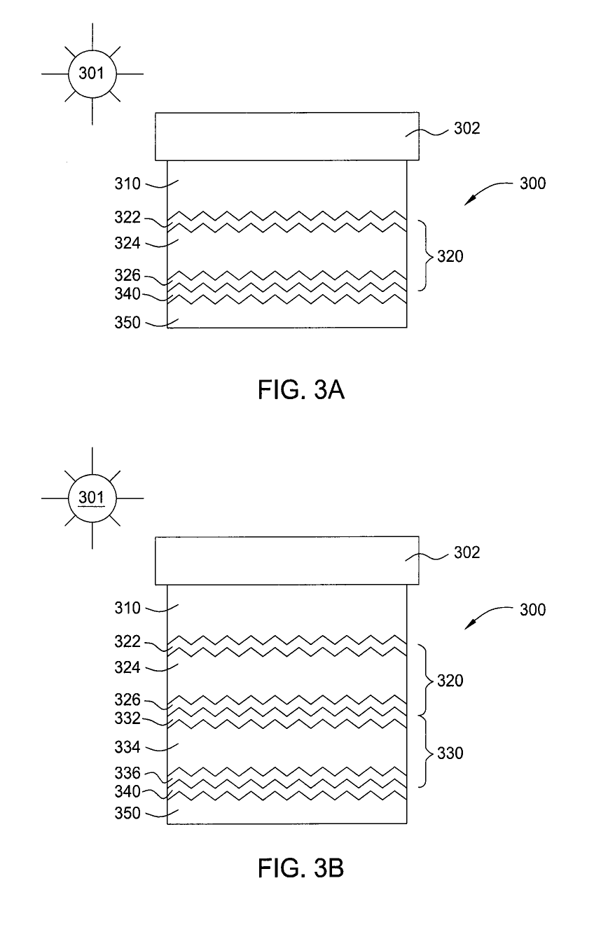

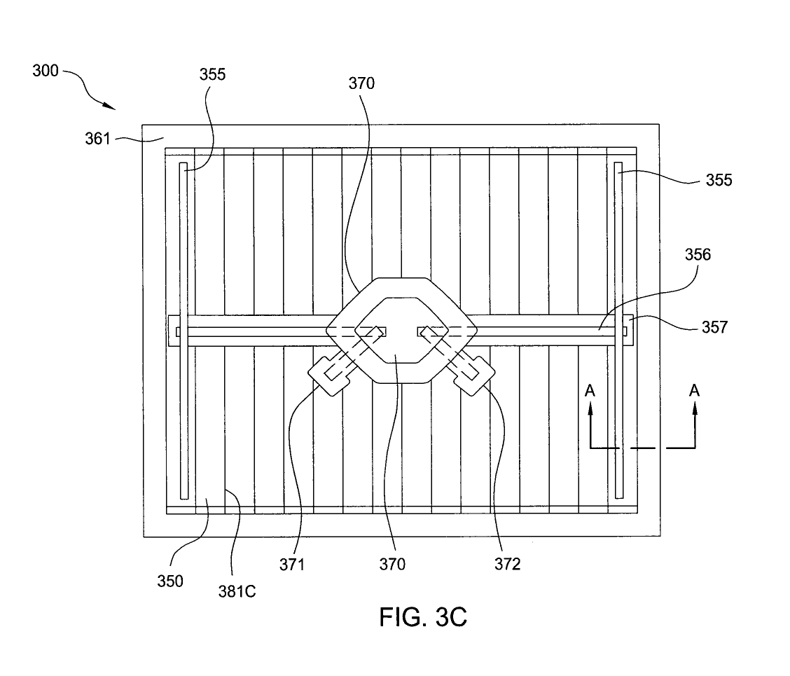

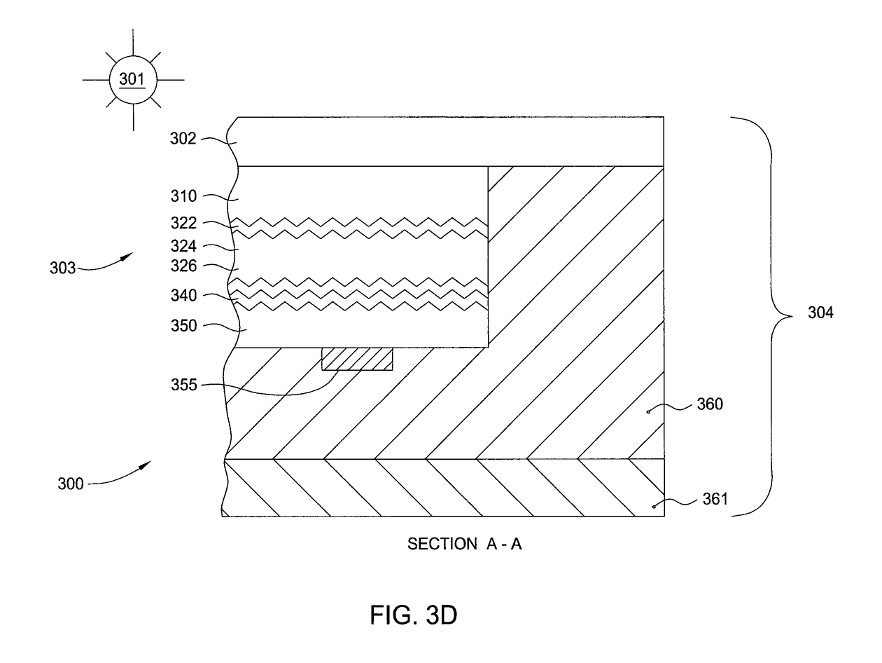

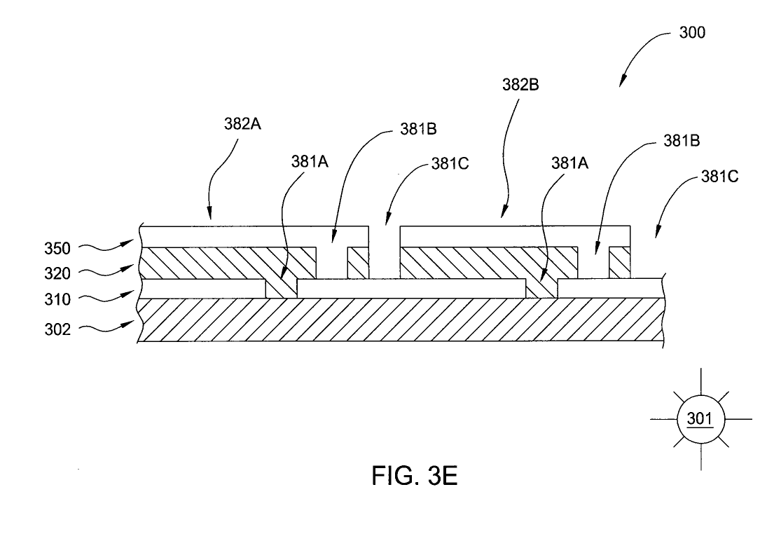

Examples of a solar cell 300 that can be formed using the process sequence(s) illustrated in FIG. 1 and the components illustrated in the solar cell production line 200 are illustrated in FIGS. 3A-3E. FIG. 3A is a simplified schematic diagram of a single-junction amorphous or micro-crystalline silicon solar cell 300 that can be formed and analyzed in the system described below.

As shown in FIG. 3A, the single-junction amorphous or micro-crystalline silicon solar cell 300 is oriented toward a light source or solar radiation 301. The solar cell 300 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size.

The solar cell 300 further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 3A, the first TCO layer 310 is textured, and the subsequent thin films deposited thereover generally follow the topography of the surface below it.

In one configuration, the first p-i-n junction 320 may comprise a p-type amorphous silicon layer 322, an intrinsic-type amorphous silicon layer 324 formed over the p-type amorphous silicon layer 322, and an n-type amorphous silicon layer 326 formed over the intrinsic-type amorphous silicon layer 324. In one example, the p-type amorphous silicon layer 322 may be formed to a thickness between about 60 Å and about 300 Å, the intrinsic-type amorphous silicon layer 324 may be formed to a thickness between about 1,500 Å and about 3,500 Å, and the n-type amorphous silicon layer 326 may be formed to a thickness between about 100 Å and about 500 Å. The back contact layer 350 may include, but is not limited to, a material selected from the group consisting of Al, Ag, Ti, Cr, Au, Cu, Pt, alloys thereof, and combinations thereof.

FIG. 3B is a schematic diagram of an embodiment of a solar cell 300, which is a multi-junction solar cell that is oriented toward the light or solar radiation 301. The solar cell 300 comprises a substrate 302, such as a glass substrate, polymer substrate, metal substrate, or other suitable substrate, with thin films formed thereover. The solar cell 300 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340.

In the embodiment shown in FIG. 3B, the first TCO layer 310 is textured, and the subsequent thin films deposited thereover generally follow the topography of the surface below it. The first p-i-n junction 320 may comprise a p-type amorphous silicon layer 322, an intrinsic-type amorphous silicon layer 324 formed over the p-type amorphous silicon layer 322, and an n-type microcrystalline silicon layer 326 formed over the intrinsic-type amorphous silicon layer 324. In one example, the p-type amorphous silicon layer 322 may be formed to a thickness between about 60 Å and about 300 Å, the intrinsic-type amorphous silicon layer 324 may be formed to a thickness between about 1,500 Å and about 3,500 Å, and the n-type microcrystalline semiconductor layer 326 may be formed to a thickness between about 100 Å and about 400 Å.

The second p-i-n junction 330 may comprise a p-type microcrystalline silicon layer 332, an intrinsic-type microcrystalline silicon layer 334 formed over the p-type microcrystalline silicon layer 332, and an n-type amorphous silicon layer 336 formed over the intrinsic-type microcrystalline silicon layer 334. In one example, the p-type microcrystalline silicon layer 332 may be formed to a thickness between about 100 Å and about 400 Å, the intrinsic-type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to, a material selected from the group consisting of Al, Ag, Ti, Cr, Au, Cu, Pt, alloys thereof, and combinations thereof.

FIG. 3C is a plan view that schematically illustrates an example of the rear surface of a formed solar cell 300 that has been produced in the production line 200. FIG. 3D is a side cross-sectional view of a portion of the solar cell 300 illustrated in FIG. 3C (see section A-A). While FIG. 3D illustrates the cross-section of a single-junction cell similar to the configuration described in FIG. 3A, this is not intended to be limiting as to the scope of the invention described herein.

As shown in FIGS. 3C and 3D, the solar cell 300 may contain a substrate 302, the solar cell device elements (e.g., reference numerals 310-350), one or more internal electrical connections (e.g., side-buss 355, cross-buss 356), a layer of bonding material 360, a back glass substrate 361, and a junction box 370. The junction box 370 may generally contain two connection points 371, 372 that are electrically connected to portions of the solar cell 300 through the side-buss 355 and the cross-buss 356, which are in electrical communication with the back contact layer 350 and active regions of the solar cell 300. To avoid confusion relating to the actions specifically performed on the substrates 302 in the discussion below, a substrate 302 having one or more of the deposited layers (e.g., reference numerals 310-350) and/or one or more internal electrical connections (e.g., side-buss 355, cross-buss 356) disposed thereon is generally referred to as a device substrate 303. Similarly, a device substrate 303 that has been bonded to a back glass substrate 361 using a layer of bonding material 360 is referred to as a composite solar cell structure 304.

FIG. 3E is a schematic cross-section of a solar cell 300 illustrating various scribed regions used to form the individual cells 382A-382B within the solar cell 300. As illustrated in FIG. 3E, the solar cell 300 includes a transparent substrate 302, a first TCO layer 310, a first p-i-n junction 320, and a back contact layer 350.

Three laser scribing steps may be performed to produce trenches 381A, 381B, and 381C, which are generally required to form a high-efficiency solar cell device. Although formed together on the substrate 302, the individual cells 382A and 382B are isolated from each other by the insulating trench 381C formed in the back contact layer 350 and the first p-i-n junction 320. In addition, the trench 381B is formed in the first p-i-n junction 320 so that the back contact layer 350 is in electrical contact with the first TCO layer 310.

In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. While a single-junction-type solar cell is illustrated in FIG. 3E, this configuration is not intended to be limiting to the scope of the invention described herein.

### General Solar Cell Formation Process Sequence

Referring to FIGS. 1 and 2, the process sequence 100 generally starts at step 102 in which a substrate 302 is loaded into the loading module 202 found in the solar cell production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar device and thus reduces the solar cell device cost, facilities costs, and production costs of the finally formed solar cell device. However, typically, it is advantageous to receive “raw” substrates 302 that have a transparent conducting oxide (TCO) layer (e.g., first TCO layer 310) already deposited on a surface of the substrate 302 before it is received into the system in step 102. If a conductive oxide layer, such as TCO layer, is not deposited on the surface of the “raw” substrates, then a front contact formation step (step 107), which is discussed below, needs to be performed on a surface of the substrate 302.

In one embodiment, the substrates 302 or 303 are loaded into the solar cell production line 200 in a sequential fashion, and thus do not use a cassette or batch-style substrate loading system. In the next step, step 104, the surfaces of the substrate 302 are prepared to prevent yield issues later on in the process. In one embodiment of step 104, the substrate is inserted into a front end substrate seaming module 204 that is used to prepare the edges of the substrate 302 or 303 to reduce the likelihood of damage, such as chipping or particle generation, from occurring during the subsequent processes.

Next, the substrate 302 or 303 is transported to the cleaning module 206, in which step 106, or a substrate cleaning step, is performed on the substrate 302 or 303 to remove any contaminants found on the surface thereof. Common contaminants may include materials deposited on the substrate 302 or 303 during the substrate forming process (e.g., glass manufacturing process) and/or during shipping or storing of the substrates 302 or 303. Typically, the cleaning module 205 uses wet chemical scrubbing and rinsing steps to remove any undesirable contaminants.

In the next step, or step 108, separate cells are electrically isolated from one another via scribing processes. Contamination particles on the TCO surface and/or on the bare glass surface can interfere with the scribing procedure. In one embodiment, the cleaning module 205 is available from the Energy and Environment Solutions division of Applied Materials, Inc. of Santa Clara, Calif.

Referring to FIGS. 1 and 2, in one embodiment, prior to performing step 108 the substrates 302 are transported to a front end processing module (not illustrated in FIG. 2) in which a front contact formation process, or step 107, is performed on the substrate 302. In one embodiment, the front end processing module is similar to the processing module 218 discussed below. In step 107, the one or more substrate front contact formation steps may include one or more preparation, etching, and/or material deposition steps that are used to form the front contact regions on a bare solar cell substrate 302. In one embodiment, step 107 generally comprises one or more PVD steps that are used to form the front contact region on a surface of the substrate 302. In one embodiment, the front contact region contains a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer. In one embodiment, the front end processing module is an ATONTM PVD 5.7 tool available from Applied Materials, Inc. of Santa Clara, Calif. in which one or more processing steps are performed to deposit the front contact formation steps. In another embodiment, one or more CVD steps are used to form the front contact region on a surface of the substrate 302.

Next, the device substrate 303 is transported to the scribe module 208 in which step 108, or a front contact isolation step, is performed on the device substrate 303 to electrically isolate different regions of the device substrate 303 surface from each other. In step 108, material is removed from the device substrate 303 surface by use of a material removal step, such as a laser ablation process.

Next, the device substrate 303 is transported to the cleaning module 210 in which step 110, or a pre-deposition substrate cleaning step, is performed on the device substrate 303 to remove any contaminants found on the surface of the device substrate 303 after performing the cell isolation step 108. Typically, the cleaning module 210 uses wet chemical scrubbing and rinsing steps to remove any undesirable contaminants found on the device substrate 303 surface after performing the cell isolation step. In one embodiment, a cleaning process similar to the processes described in step 105 above is performed on the device substrate 303 to remove any contaminants on the surface(s) of the device substrate 303.

Next, the device substrate 303 is transported to the processing module 212 in which step 112, which comprises one or more photoabsorber deposition steps, is performed on the device substrate 303. In step 112, the one or more photoabsorber deposition steps may include one or more preparation, etching, and/or material deposition steps that are used to form the various regions of the solar cell device. Step 112 generally comprises a series of sub-processing steps that are used to form one or more p-i-n junctions. In one embodiment, the one or more p-i-n junctions comprise amorphous silicon and/or microcrystalline silicon materials. In general, the one or more processing steps are performed in one or more cluster tools (e.g., cluster tools 212A-212D) found in the processing module 212 to form one or more layers in the solar cell device formed on the device substrate 303.

In one embodiment, the device substrate 303 is transferred to an accumulator 211A prior to being transferred to one or more of the cluster tools 212A-212D. In one embodiment, in cases where the solar cell device is formed to include multiple junctions, such as the tandem junction solar cell 300 illustrated in FIG. 3B, the cluster tool 212A in the processing module 212 is adapted to form the first p-i-n junction 320 and cluster tools 212B-212D are configured to form the second p-i-n junction 330. In such an embodiment, the device substrate 303 may optionally be transferred into a spectrographic inspection module 215 for a corresponding film characterization step 115 following processing in the first cluster tool 212A. In one embodiment, the optional inspection module 215 is configured within the overall processing module 212.

In one embodiment of the process sequence 100, a cool-down step, or step 113, is performed after step 112 has been performed. The cool-down step is generally used to stabilize the temperature of the device substrate 303 to assure that the processing conditions seen by each device substrate 303 in the subsequent processing steps are repeatable.

In one embodiment, the cool-down step 113 is performed in one or more of the substrate supporting positions found in one or more accumulators 211. In one configuration of the production line, as shown in FIG. 2, the processed device substrates 303 may be positioned in one of the accumulators 211B for a desired period of time to control the temperature of the device substrate 303. In one embodiment, the system controller 290 is used to control the positioning, timing, and movement of the device substrates 303 through the accumulator(s) 211 to control the temperature of the device substrates 303 before proceeding down stream through the production line.

Next, the device substrate 303 is transported to the scribe module 216 in which step 114, or the interconnect formation step, is performed on the device substrate 303 to electrically isolate various regions of the device substrate 303 surface from each other. In step 114, material is removed from the device substrate 303 surface by use of a material removal step, such as a laser ablation process. As shown in FIG. 3E, in one embodiment, the trench 381B is formed in the first p-i-n junction 320 layers by use of a laser scribing process.

Next, the device substrate 303 is transported to the processing module 218 in which one or more substrate back contact formation steps, or step 118, are performed on the device substrate 303. In step 118, the one or more substrate back contact formation steps may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from a group consisting of zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 350. In one embodiment, the one or more processing steps are performed using an ATONTM PVD 5.7 tool available from Applied Materials, Inc. of Santa Clara, Calif. In another embodiment, one or more CVD steps are used to form the back contact layer 350 on the surface of the device substrate 303.

In one embodiment, the solar cell production line 200 has at least one accumulator 211 positioned after the processing module 218. During production, the accumulators 211D may be used to provide a ready supply of substrates to the scribe modules 220, and/or provide a collection area where substrates coming from the processing module 218 can be stored if the scribe modules 220 go down or cannot keep up with the throughput of the processing module 218.

Next, the device substrate 303 is transported to the scribe module 220 in which step 120, or a back contact isolation step, is performed on the device substrate 303 to electrically isolate the plurality of solar cells contained on the substrate surface from each other. In step 120, material is removed from the substrate surface by use of a material removal step, such as a laser ablation process. As shown in FIG. 3E, in one embodiment, the trench 381C is formed in the first p-i-n junction 320 and back contact layer 350 by use of a laser scribing process.

Next, the device substrate 303 is optionally transported to the substrate sectioning module 224 in which a substrate sectioning step 124 is used to cut the device substrate 303 into a plurality of smaller device substrates 303 to form a plurality of smaller solar cell devices.

Referring back to FIGS. 1 and 2, the device substrate 303 is next transported to the seamer/edge deletion module 226 in which a substrate surface and edge preparation step 126 is used to prepare various surfaces of the device substrate 303 to prevent yield issues later on in the process.

Next, the device substrate 303 is transported to the pre-screen module 228 in which optional pre-screen steps 128 are performed on the device substrate 303 to assure that the devices formed on the substrate surface meet a desired quality standard. Next, the device substrate 303 is transported to the cleaning module 230 in which step 130, or a pre-lamination substrate cleaning step, is performed on the device substrate 303 to remove any contaminants found on the surface of the substrates 303 after performing steps 122-127.

Next, the substrate 303 is transported to a bonding wire attach module 231 in which step 131, or a bonding wire attach step, is performed on the substrate 303. Step 131 is used to attach the various wires/leads required to connect the various external electrical components to the formed solar cell device. Typically, the bonding wire attach module 231 is an automated wire bonding tool that is advantageously used to reliably and quickly form the numerous interconnects that are often required to form the large solar cells formed in the production line 200.

In one embodiment, the bonding wire attach module 231 is used to form the side-buss 355 (FIG. 3C) and cross-buss 356 on the formed back contact region (step 118). In this configuration the side-buss 355 may be a conductive material that can be affixed, bonded, and/or fused to the back contact layer 350 found in the back contact region to form a good electrical contact.

The cross-buss 356, which is electrically connected to the side-buss 355 at the junctions, can be electrically isolated from the back contact layer(s) of the solar cell by use of an insulating material 357, such as an insulating tape. The ends of each of the cross-busses 356 generally have one or more leads that are used to connect the side-buss 355 and the cross-buss 356 to the electrical connections found in a junction box 370, which is used to connect the formed solar cell to the other external electrical components.

In the next step, step 132, a bonding material 360 (FIG. 3D) and “back glass” substrate 361 are prepared for delivery into the solar cell formation process (i.e., process sequence 100). The preparation process is generally performed in the glass lay-up module 232, which generally comprises a material preparation module 232A, a glass loading module 232B, a glass cleaning module 232C, and a glass inspection module 232D. The back glass substrate 361 is bonded onto the device substrate 303 formed in steps 102-131 above by use of a laminating process (step 134 discussed below). In general, step 132 requires the preparation of a polymeric material that is to be placed between the back glass substrate 361 and the deposited layers on the device substrate 303 to form a hermetic seal to prevent the environment from attacking the solar cell during its life.

Referring to FIG. 2, step 132 generally comprises a series of sub-steps in which a bonding material 360 is prepared in the material preparation module 232A, the bonding material 360 is then placed over the device substrate 303, and the back glass substrate 361 is loaded into the loading module 232B. The back glass substrate 361 is washed by the cleaning module 232C. The back glass substrate 361 is placed over the bonding material 360 and the device substrate 303.

In one embodiment, the material preparation module 232A is adapted to receive the bonding material 360 in a sheet form and perform one or more cutting operations to provide a bonding material, such as Polyvinyl Butyral (PVB) or Ethylene Vinyl Acetate (EVA) that is sized to form a reliable seal between the back glass substrate 361 and the solar cells formed on the device substrate 303. In general, when using bonding materials 360 that are polymeric, it is desirable to control the temperature (e.g., 16-18° C.) and relative humidity (e.g., RH 20-22%) of the solar cell production line 200 where the bonding material 360 is stored and integrated into the solar cell device to assure that the attributes of the bond formed in the bonding module 234 (discussed below) are repeatable and the dimensions of the polymeric material is stable. It is generally desirable to store the bonding material prior to use in a temperature- and humidity-controlled area (e.g., T=6-8° C.; RH=20-22%).

The tolerance stack-up of the various components in the bonded device (Step 134) can be an issue when forming large solar cells. Therefore accurate control of the bonding material properties and tolerances of the cutting process are required to assure that a reliable hermetic seal is formed. In one embodiment, PVB may be used to advantage due to its UV stability, moisture resistance, thermal cycling, good US fire rating, compliance with International Building Code, low cost, and reworkable thermo-plastic properties.

In one example, a 30-gauge or a 45-gauge PVB material sheet is used to bond the back glass substrate 361 to the device substrate 303. In one part of step 132, the bonding material is transported and positioned over the back contact layer 350 and side-buss 355 (FIG. 3C) and cross-buss 356 (FIG. 3C) elements of device substrate 303 using an automated robotic device. In one embodiment, a robot 232D, which can be a conventional robotic device (e.g., 6-axis robot), is used to pick up and place the bonding material 360 on the device substrate 303. The device substrate 303 and bonding material 360 are then positioned to receive a back glass substrate 361, which can be placed thereon by use of the same automated robotic device used to position the bonding material 360, or a second automated robotic device. In one embodiment, a glass loading robot 232E, which can be a conventional robotic device (e.g., 6-axis robot), is used to place the back glass substrate 361 on the device substrate 303 and bonding material 360.

In the next sub-step of step 132, the back glass substrate 361 is transported to the cleaning module 232C in which a substrate cleaning step is performed on the substrate 361 to remove any contaminants found on the surface of the substrate 361. The prepared back glass substrate 361 is then positioned over the bonding material and device substrate 303 by use of an automated robotic device.

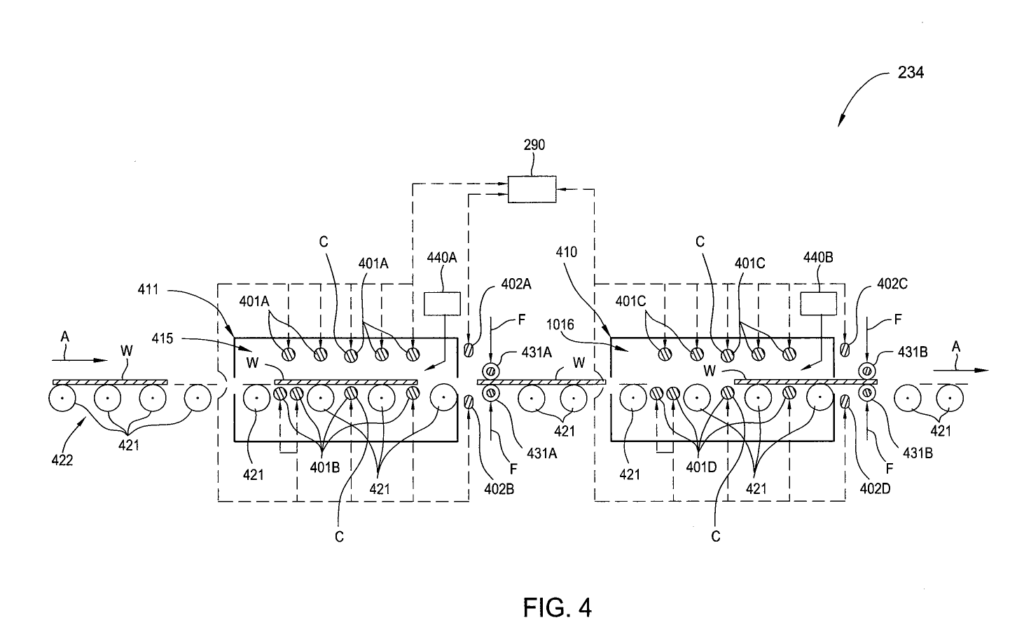

Next, the device substrate 303, the back glass substrate 361, and the bonding material 360 are transported to the bonding module 234 in which step 134, or lamination steps, are performed to bond the backside glass substrate to the solar cell devices formed in steps 102-130 discussed above. In step 134, a bonding material 360, such as Polyvinyl Butyral (PVB) or Ethylene Vinyl Acetate (EVA), is sandwiched between the backside glass substrate 361 and the solar cells, and heat and pressure is applied to the structure to form a bonded and sealed device using various heating elements and other devices found in the bonding module 234, which are discussed below. The device substrate 303, the back glass substrate 361, and bonding material 360 thus form a composite solar cell structure 304 (FIG. 3D) that at least partially encapsulates the active regions of the solar cell 300. In one embodiment, at least one hole formed in the back glass substrate 361 remains at least partially uncovered by the bonding material 360 to allow portions of the cross-buss 356 or the side-buss 355 to remain exposed so that electrical connections can be made to these regions of the solar cell device in future steps (i.e., step 138). The processes and apparatus used to perform step 134 and some of its sub-steps are further described below in conjunction with FIGS. 4 and 6-13.

Next, the composite solar cell structure 304 is transported to the autoclave module 236 in which step 136, or autoclave steps are performed on the composite structure to remove trapped gases in the bonded structure and assure that a good bond is formed during step 134. In step 134, a bonded structure is inserted in the processing region of the autoclave module where heat and high-pressure gases are delivered to reduce the amount of trapped gas and improve the properties of the bond between the substrate 302, back glass substrate, and bonding material 360. The processes performed in the autoclave are also useful to assure that the stress in the glass and bonding layer (e.g., PVB layer) are more controlled to prevent future failures of the hermetic seal or failure of the glass due to the stress induced during the bonding/lamination process. In one embodiment, it may be desirable to heat the substrate, back glass substrate 361, and bonding material 360 to a temperature that causes stress relaxation in the one or more of the components formed in the composite solar cell structure 304.

Next, the solar cell structure 304 is transported to the junction box attachment module 238 in which junction box attachment steps 138 are performed on the formed solar cell structure 304. The junction box attachment module 238, used during step 138, is used to install a junction box 370 (FIG. 3C) on a partially formed solar cell. The installed junction box 370 acts as an interface between the external electrical components that will connect to the formed solar cell, such as other solar cells or a power grid, and the internal electrical connection points, such as the leads, formed during step 131. In one embodiment, the junction box 370 contains one or more junction box terminals, such as connection points 371, 372, so that the formed solar cell can be easily and systematically connected to other external devices to deliver the generated electrical power.

Next, the solar cell structure 304 is transported to the device testing module 240, in which device screening and analysis steps 140 are performed on the solar cell structure 304 to assure that the devices formed on the solar cell structure 304 surface meet desired quality standards. In one embodiment, the device testing module 240 is a solar simulator module that is used to qualify and test the output of the one or more formed solar cells.

Next, the solar cell structure 304 is transported to the support structure module 241, in which support structure mounting steps 141 are performed on the solar cell structure 304 to provide a complete solar cell device that has one or more mounting elements attached to the solar cell structure 304 formed using steps 102-140 to a complete solar cell device that can easily be mounted and rapidly installed at a customer's site.

Next, the solar cell structure 304 is transported to the unload module 242 in which step 142, or device unload steps, are performed on the substrate to remove the formed solar cells from the solar cell production line 200.

In one embodiment of the solar cell production line 200, one or more regions in the production line are positioned in a clean room environment to reduce or prevent contamination from affecting the solar cell device yield and useable lifetime. In one embodiment, as shown in FIG. 2, a class 10,000 clean room space 250 is placed around the modules used to perform steps 108-118 and steps 130-134.

Referring to FIGS. 1 and 2, in one embodiment of the solar cell production line 200, one or more accumulators 211A-211D are inserted to provide buffering capability at various points within the solar cell production line 200 to achieve a desired throughput during steady state and fault state conditions (e.g., one or more modules 202-241 is in a fault state). As shown in FIG. 2, in one embodiment, the solar cell production line 200 has at least one accumulator 211 (e.g., accumulator 211A) positioned before the one or more cluster tools 212A-212D found in the processing module 212 and at least one accumulator 211 (e.g., accumulator 211B) positioned after the one or more cluster tools 212A-212D. During the production of solar cells, it is generally desirable to load the accumulators 211A with two or more substrates to assure that the one or more cluster tools 212A-212D have a ready supply of substrates, and provide a collection area where substrates coming from the upstream processes can be stored if one or more of the cluster tools 212A-212D goes down.

### Bonding Module Design and Processes

As noted above, during step 134, or the lamination step, one or more process steps are performed to bond the backside glass substrate to the solar cell devices formed in steps 102-132 to form a bonded composite solar cell structure 304 (FIG. 3D). Step 134 is thus used to seal the active elements of the solar cell from the external environment to prevent the premature degradation of a formed solar cell during its useable life. An exemplary bonding module 234 and method of using the same are further described in U.S. patent application Ser. No. 12/359,250, filed Jan. 23, 2009, which is herein incorporated by reference.

FIG. 4 illustrates one or more embodiments of a bonding module 234 which may be useful to perform the lamination process, discussed below. FIG. 4 is a schematic cross-sectional view of the bonding module 234 that illustrates some of the common components found within this module. Generally, the bonding module 234 contains a preheat module 411, a lamination module 410, a system controller 290, and a conveyor system 422. The conveyor system 422 generally contains a plurality of support rollers 421 that are designed to support, move, and/or position a device substrate 303, the back glass substrate 361, and the bonding material 360, or hereafter composite solar cell structure 304. As discussed in more detail below, a pre-patterned bonding material 360 may be provided to help prevent bubble formation during the lamination process. As shown in FIG. 4, a solar cell can be transferred into and through the bonding module 234 following the paths Ai and Ao.

The preheat module 411 generally contains a plurality of support rollers 421, a plurality of heating elements 401A, 401B, two or more temperature sensors (e.g., temperature sensors 402A, 402B), and one or more compression rollers 431A. The plurality of support rollers 421 are adapted to support the composite solar cell structure 304 while it is positioned within the processing region 415 of the preheat module 411 and are configured to withstand the temperatures created by the heating elements 401A, 401B during normal processing. In one embodiment, the preheat module 411 also contains a fluid delivery system 440A that is use to deliver a desired flow of a fluid, such as air or nitrogen (N2), through the processing region 415 during processing.

The plurality of heating elements 401A, 401B are typically lamps (e.g., IR lamps), resistive heating elements, or other heat generating devices that are controlled by the system controller 290 to deliver a desired amount of heat to desired regions of the composite solar cell structure 304 during processing. In one embodiment, a plurality of heating elements 401A are positioned above the composite solar cell structure 304, and a plurality of heating elements 401B are positioned below the composite solar cell structure 304. In one embodiment, the heating elements 401A, 401B are oriented substantially perpendicular to the direction of travel of the substrate, and the energy delivered by the lamps creates a uniform temperature profile across the substrate as it is continually moved through the processing region 415.

The compression rollers 431A are adapted to provide a desired amount of force F to the composite solar cell structure 304 to help remove the air bubbles found within the composite solar cell structure 304 and evenly distribute the bonding material within the composite solar cell structure 304 after performing the preheat process step. The compression rollers 431A are generally configured to receive the composite solar cell structure 304 after it has been sufficiently heated in the preheat module 411.

Referring to FIG. 4, the preheat module 411 also contains two temperatures sensors 402A, 402B that are adapted to measure the temperature of regions of the composite solar cell structure 304 during the preheat process. The temperature sensors may be a non-contact-type temperature sensor, such as a conventional pyrometer, or a conventional contacting-type of temperature sensor. In one embodiment, the preheat module 411 contains a top temperature sensor 402A that is adapted to measure the temperature of the top of the composite solar cell structure 304 and a bottom temperature sensor 402B that is adapted to measure the temperature of the bottom of the composite solar cell structure 304 during or after processing. In one embodiment, the top temperature sensor 402A and a bottom temperature sensor 402B are positioned over one another so that the difference in temperature between the top side and bottom side of the composite solar cell structure 304 at the same position on the substrate can be simultaneously measured.

In general, during the preheat process the composite solar cell structure 304 is controllably heated as it passes through the processing region 415 by use of the one more of the heating elements 401A, 401B disposed therein. In one embodiment, at least one of the top heating elements 401A and at least one of the bottom heating elements 401B are close loop controlled using the system controller 290 and at least one temperature sensor 402B positioned on the top of the substrate and at least one temperature sensor 402B positioned on the bottom of the substrate. After the substrate is preheated, a desired force is applied to one or more sides of the preheated substrate by use of the one or more compression rollers 431A using one or more controlled force generating elements. The applied force supplied by the one or more compression rollers 431A may be between about 200 [N/cm] and about 600 [N/cm].

The lamination module 410 generally contains a plurality of support rollers 421, a plurality of heating elements 401C, 401D, two or more temperature sensors (e.g., temperature sensors 402C, 402D), and one or more compression rollers 431B. The plurality of support rollers 421 are adapted to support the composite solar cell structure 304 while it is positioned within the processing region 416 of the lamination module 410 and are configured to withstand the temperatures achieved during normal thermal processing. In one embodiment, the lamination module 410 also contains a fluid delivery system 440B that is used to deliver a desired flow of a fluid through the processing region 416 during processing. In one embodiment, the fluid delivery system 440B is a fan assembly that is adapted to deliver a desired flow of air across one or more surfaces of the substrate disposed within the processing region 416 by use of commands sent from the system controller 290.

The plurality of heating elements 401C, 401D are typically lamps (e.g., IR lamps), resistive heating elements, or other heat-generating devices that are controlled by the system controller 290 to deliver a desired amount of heat to desired regions of the composite solar cell structure 304 during processing. In one embodiment, a plurality of heating elements 401C are positioned above the composite solar cell structure 304, and a plurality of heating elements 401D are positioned below the composite solar cell structure 304. In one embodiment, the heating elements 401C, 401D are oriented substantially perpendicular to the direction of travel of the substrate, and the energy delivered by the lamps creates a uniform temperature profile across the substrate as it is moved through the processing region.

The one or more compression rollers 431B are adapted to provide a desired amount of force F to the composite solar cell structure 304 (i.e., composite structure) to help remove the air bubbles found within the composite solar cell structure 304 and evenly distribute the bonding material within the composite solar cell structure 304. The compression rollers 431B are generally configured to receive the composite solar cell structure 304 after it has been sufficiently heated in the lamination module 410. In one embodiment, as shown in FIG. 4, a pair of compression rollers 431B are used to remove any trapped air from the substrate by applying a force F to both sides of the composite solar cell structure 304 by the compression rollers 431B by use of a conventional electric or pneumatic force generating element.

Referring to FIG. 4, the lamination module 410 also contains two temperatures sensors 402C, 402D that are adapted to measure the temperature of regions of the composite solar cell structure 304 during the lamination process. The temperature sensors may be non-contact-type temperature sensor, such as a conventional pyrometer, or a conventional contact-type temperature sensor. In one embodiment, the lamination module 410 contains a top temperature sensor 402C that is adapted to measure the temperature of the top of the composite solar cell structure 304 and a bottom temperature sensor 402D that is adapted to measure the temperature of the bottom of the composite solar cell structure 304 during or after processing. In one embodiment, the top temperature sensor 402C and a bottom temperature sensor 402D are positioned one over another, so that the difference in temperature between the top side and bottom side of the composite solar cell structure 304 can be simultaneously measured. In one embodiment, an array of pairs of temperature sensors 402C, 402D are positioned over desired areas of the composite solar cell structure 304 so that top and bottom temperature readings at different areas of the composite solar cell structure 304 can be measured.

Therefore, after performing the preheat process, a lamination process is performed in the lamination module 410. During the lamination process, the composite solar cell structure 304 is controllably heated as it passes through the processing region 416 by use of the one more of the heating elements 401C, 401D disposed therein. In one embodiment, at least one of the top heating elements 401C and at least one of the bottom heating elements 401D are close loop controlled, using the system controller 290 and at least one temperature sensor 402C positioned on the top of the substrate and at least one temperature sensor 402D positioned on the bottom of the substrate. After the substrate is heated in the lamination module, a desired force is applied to one or more sides of the composite substrate by use of the one or more compression rollers 431B, using one or more controlled force generating elements. The applied force supplied by the one or more compression rollers 431B may be between about 200 [N/cm] and about 600 [N/cm].

### Autoclave Module Design and Processes

As discussed above, in step 134, the composite solar cell structure is inserted in the processing region of the autoclave module, where heat and pressure is applied to the partially formed solar cells to reduce the amount of trapped gas disposed between bonding material 360 and the back glass substrate 361, substrate 302 or the back contact layer 350 to prevent environmental attack of portions of the solar cell device through the regions of trapped gas. Use of the autoclave process is also used to improve the properties of the bond between the substrate 302, back glass substrate and bonding material 360. The processes performed in the autoclave are also useful to assure that the stress in the glass and bonding layer (e.g., PVB layer) are more controlled to prevent future failures of the hermetic seal or failure of the glass due to the stress induced during the bonding/lamination process.

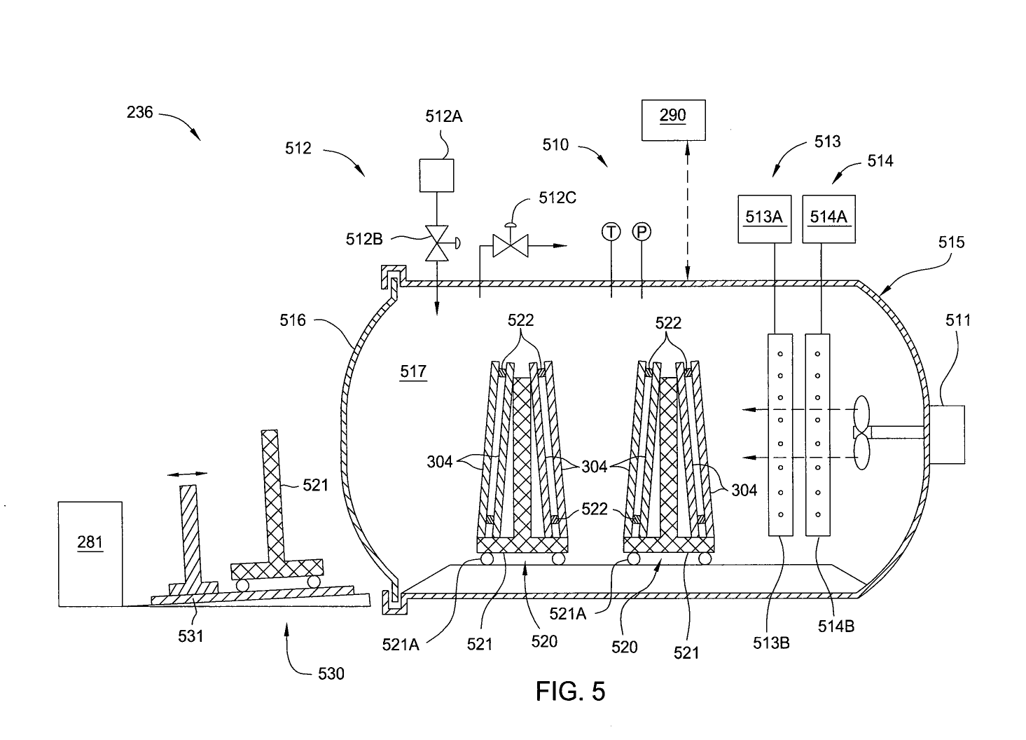

FIG. 5 illustrates a side cross-sectional view of an autoclave module 236 and supporting equipment. The autoclave module 236 will generally contain a vessel assembly 510, one or more substrate racks 520, and a loading system 530. The vessel assembly 510 generally contains a fluid movement device 511, compressor 512, heating unit 513, cooling unit 514, and a vessel 515. The vessel 515 has a door 516 that is configured to enclose the substrate racks 520 and composite solar cell structures 304 disposed thereon in a processing region 517 during processing. As shown in FIG. 5, the door 516 is closed and sealed against the vessel 515. The compressor 512, system controller 290, and pressure sensor “P” are used in combination to deliver and actively control the pressure within the processing region 517 during the autoclave process by controlling the delivery and release of a high-pressure fluid from a fluid pump 512A, valve 512B and relief valves 512C. In one embodiment, the compressor 512 is adapted to provide compressed air at pressure greater than about 13 Bar to the processing region 517 of the autoclave module 236 during processing. In another embodiment, the compressor 512 is adapted to provide compressed air at pressure between about 13 Bar and about 15 Bar to the processing region 517 during processing.

To control the temperature of the composite solar cell structures 304 during the autoclave process, the system controller 290 and temperature sensor “T” are used in combination to control the amount of heat that is transferred to the composite solar cell structures 304 positioned in the processing region 517 by use of the components contained in the heating unit 513 and the cooling unit 514. The heating unit 513 generally contains a heater controller 513A and a plurality of heating elements 513B (e.g., thermally-controlled resistance heating elements) that are in thermal communication with the composite solar cell structures 304 disposed within the processing region 517. Similarly, the cooling unit 514 contains a cooling unit controller 514A and a plurality of cooling elements 514B that are in thermal communication with the composite solar cell structures 304 disposed within the processing region 517. The cooling elements 514B may comprise a series of fluid-containing channels, in which a fluid exchanging medium is provided from the cooling unit controller 514A, to cool the components contained in the processing region 517. In one example, the heating elements 513B and/or cooling elements 514B are disposed within the processing region 517 and are adapted to add and/or remove heat from the composite solar cell structures 304 by convective heat transfer supplied by movement of the high-pressure gas contained in the processing region 517 during processing by use of the fluid movement device 511 (e.g., mechanical fan). The fluid movement device 511 is configured to provide motion to the fluid contained in the processing region 517 during processing to also reduce the variation in temperature throughout the processing region 517. In one embodiment, the temperature in the processing region is maintained between about 140° C. and about 160° C. for a time between about 1 and about 4 hours. The autoclave processing temperatures, pressures, and times will vary by the type of bonding material that is used, and as one or more of the process variables are altered.

The loading system 530 is generally configured to deliver and remove one or more of the racks 520 to the processing region 517 of the vessel 515 prior to and after processing. The loading system 530 generally contains an automated material handling device 531, for example, a conveyor or a robotic device, which is used to transfer the racks 520 to and from the processing region 517 of the vessel 515 in an automated fashion.

The one or more substrate racks 520 generally include one or more regions of shelves 521 that are adapted to support the composite solar cell structures 304 during processing. In one embodiment, each substrate rack 520 contains wheels 521A that allows the racks to be easily moved and positioned within the production line 200. Each of the composite solar cell structures 304 are spaced a desired distance apart to assure that temperature uniformity and pressures applied to the composite solar cell structures 304 are uniform. In one embodiment, to assure that the substrates see the same processing conditions, one or more spacers 522 are disposed between and in contact with both adjacent composite solar cell structures 304 to assure that the spacing between the adjacent composite solar cell structures 304 is uniform. In one embodiment, three or more spacers are positioned between adjacent composite solar cell structures 304. In one example, the spacers 522 are adapted to space adjacent composite solar cell structures 304 between about 5 mm and about 15 mm apart.

In general, the autoclave module 236 may be transferrably connected to the automation device 281, positioned after the bonding module 234, to receive and perform an autoclave process on one or more of the formed composite solar cell structures 304. The autoclave module 236 may also be transferrably connected to the automation device 281 positioned before the junction box attachment module 238 so that the processed substrates can be transferred to the down stream processing modules.

In one embodiment, as shown in FIG. 2A, the composite solar cell structures 304 leaving the bonding module 234 are transferred to a substrate rack 520 that is then transferred to the autoclave module 236 for processing, and then transferred to a position near the junction box attachment module 238 after processing. As shown in FIG. 2A, a plurality of substrate racks 520 are positioned to receive substrates from the automation device 281 positioned after the bonding module 234. In one embodiment, one or more robots 235A (e.g., 6-axis robot) are positioned to transfer the composite solar cell structures 304 from the automation device 281, which is positioned after the bonding module 234, and on to a moveable substrate rack 520 by use of a robotic device (e.g., automated material handling device 531). Similarly, in one embodiment, the substrate racks 520 are moved from the autoclave module to a position where a robot 235B (e.g., 6-axis robot) is able to transfer the composite solar cell structures 304 from a substrate rack 520 and on to the automation device 281 positioned before the junction box attachment module 238. In one embodiment, the substrate rack 520 may be moved to and from the autoclave module 236 in an automated fashion. In some cases it is desirable to minimize the need for and/or the amount of human intervention.

### Method of Forming Pre-Patterned Bonding Material Used for Forming a Composite Solar Cell Structure

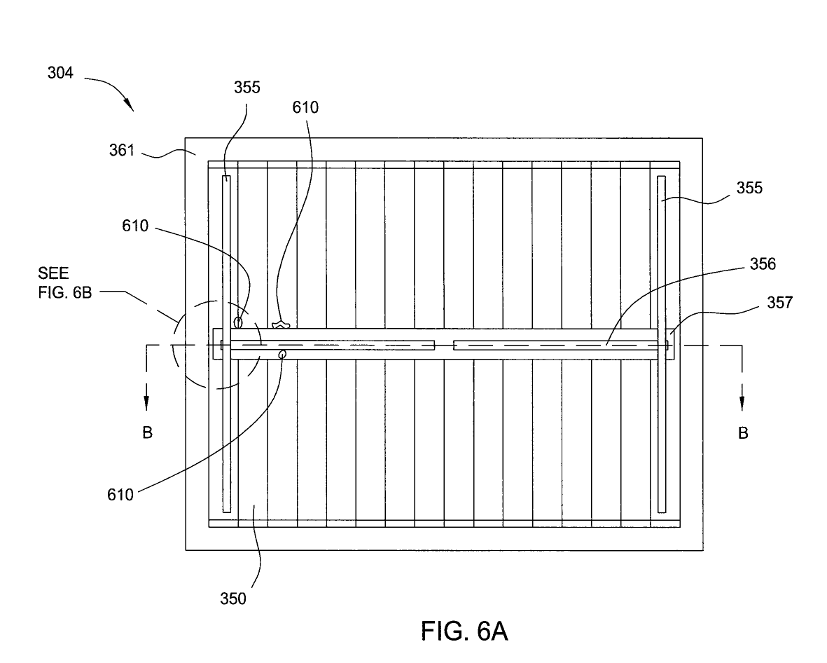

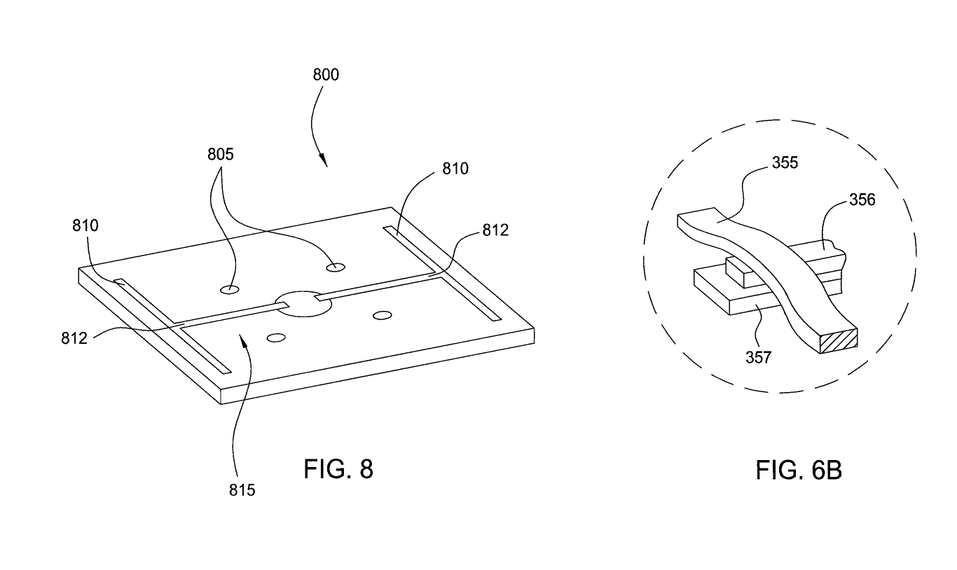

As previously set forth, steps 131-136 of the processing sequence 100 may be used to form a composite solar cell structure 304 from the device substrate 303 using the bonding wire attach module 231, the bonding module 234, and the autoclave module 236. FIG. 6A is a plane view of a composite solar cell structure 304 without the junction box attached but after lamination and autoclaving the solar cell structure 304. The back contact layer 350 may be seen through the back glass substrate 361. As previously discussed, the internal electrical connections disposed on the back of contact layer 350 may comprise the cross-buss 356 and side-buss 355 as shown in FIG. 6A. A layer of isolation type may be placed beneath the cross-buss 356. During lamination, bubbles 610 may inadvertently form between the back glass substrate 361 and the previously exposed surface of back contact layer 350 and side- and cross-busses 355, 356, creating delamination paths or even environmental exposure paths leading to device failure. Formation of bubbles during lamination may be particularly problematic around the increased step topography created by the side- and cross-busses, especially at their intersection.

FIG. 6B is a close-up isometric view of the cross-buss 356, side-buss 355, and isolation tape 357 shown on the composite solar cell structure in FIG. 6A. The close-up 6A though does not show the back contact layer 350. As can be seen, the area where the cross- and side-busses overlap may be particularly troublesome for bubble formation because of the thickness of the busses.

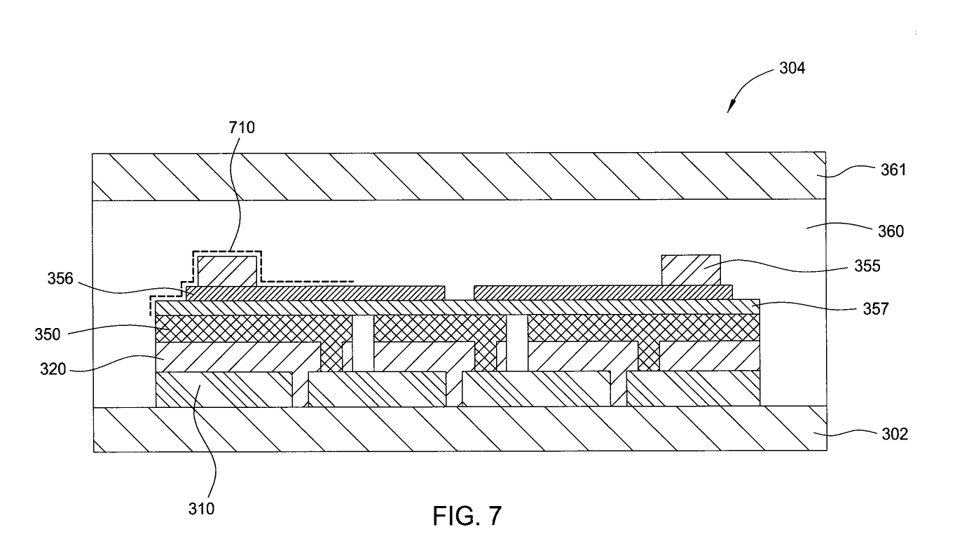

FIG. 7 is a cross-sectional view of a composite solar cell structure 304 in FIG. 6A along lines B-B. The composite solar cell 304 shown in FIG. 7 is a single-junction-type solar cell. Although a single-junction-type solar cell is shown, it should be understood that other types of solar cells may also use embodiments of the invention during their formation. A transparent conductive oxide layer 310 is deposited over a glass substrate 302. A single-junction layer 320, including one or more silicon layers, is deposited over the transparent conductive layer 310. A back contact layer 350 is deposited over the single-junction layer 320. One or more internal electrical connections, such as side- and cross-busses 355, 356, are disposed on the back contact layer 350. In some embodiments, an isolation tape 357 may be disposed between the cross-buss 356 and the back contact layer 350. At this point in the solar cell formation process, a device substrate has been formed.

Next, a bonding material 360 and backing glass substrate 361 are laminated together, forming a composite solar cell structure 304. As can be seen from the cross-sectional side view of FIG. 6A, the large thickness differences between the cross-buss 356, the side-buss 355, the isolation tape 357, and the back contact layer 350 creates an exposed surface topography 710 that increases the chance for air to be trapped between the bonding material 360 and the adjacent layers. To decrease the likelihood of bubble formation, especially at these corners near the busses and back contact layer, one embodiment of the invention provides a bonding material 360 that has been pre-patterned to match the topography 710 of an exposed surface of the device substrates. One method of embossing a mating pattern in the bonding material is shown in FIG. 8.

FIG. 8 is a work surface having an embossment according to one embodiment described herein. In this embodiment of preparing a pre-patterned bonding material 360 for a solar cell assembly, a bonding material 360 is placed over a work surface 800 having an embossment 808, wherein at least a portion of the embossment 808 corresponds to a topography 710 of an exposed surface of a device substrate 303. The embossment 808 may have the same pattern as the busses 355, 356. For example, the embossment 808 includes a side-buss surface projection 810 corresponding in length and thickness to the side-buss 355. A cross-buss surface projection 812 roughly mirrors the length and thickness of the cross-buss 356. The bonding material thickness may be 45 gauge, or 1.14 ml. In other embodiments, the bonding material thickness may be 30 gauge or 0.7 ml.

A central hole 815 corresponds to a hole in the back substrate glass 361 and bonding material 360 necessary to electrically connect the junction box with the cross-buss 356, as previously described in step 138. The bonding material may be pre-cut into sheets that match the size of the device substrate 303. Pre-cutting the bonding material may take place at material perpetration module 232A discussed above in connection with process steps 131-136.

After the bonding material 360 is placed on the work surface, the bonding material 360 is heated and then pressed onto the embossment 808 to form a mating pattern. The heating of the bonding material may include locally heating a portion of the bonding material corresponding to the topography of the exposed surface. In one embodiment, only the embossment 808 is heated to create the localized heating of the bonding material 360 along the areas of the mating pattern. Localized heating may be useful because heating up the entire bonding material 360 may cause shrinkage and negatively impact the ability of the bonding material 360 to sufficiently cover the exposed surface of the device substrate 303. The localized heating may heat portions of the bonding material to a temperature between 30 and 95° C. for imprinting the pattern on the bonding material.

In one embodiment a platen may be pressed down on the bonding material, creating a die to form the mating pattern. In other embodiments a roller may roll across the work surface to imprint the mating pattern on the bonding material 360. Additionally, various pressures may be used to press the bonding material 360 on the embossment 808 to form the mating pattern. The pressure and time of embossing are interrelated and can be adjusted to provide the desired mating pattern without negatively affecting the physical and chemical properties of the bonding material 360. Any of these disclosed methods of pre-patterning the bonding material 360 may be performed at material perpetration module 232A discussed above in connection with process steps 131-136.

A plurality of holes 805 may be used to inject air from the bottom of the work surface 800 to prevent sticking of the bonding layer 360 after embossing the mating pattern. The bonding material may easily stick to various surfaces, and injecting air through holes 805 can be used to remove the bonding material 360 from the work surface 800. In another embodiment, the embossment 808 and work surface 800 may have a coating that prevents sticking. These stick-prevention features may be particularly desirable for PVB, which tends to stick very well, especially when heated. Furthermore, local heating around the area so embossed will help minimize the overall heating instability of the bonding material 360, such as PVB.

In other embodiments of the invention, pre- and post-processing steps may be performed. One type of pre-processing step would be relaxing the bonding material 360 before placing the bonding material 360 over the work surface 800. Relaxing the bonding material, such as PVB, may help the PVB layer to flow when it passes though the rollers in the lamination step previously discussed, further helping to prevent bubble formation. Relaxing the bonding material may also prevent the edges from pulling away from the glass substrate during lamination and further increasing the chance of atmospheric contamination. Additionally, relaxed bonding material may not move as much, preventing inadvertent movement of the cross- and side-busses during lamination. Bonding material that moves too much may push and fight against the busses and increase the chance for bubble formation.

Relaxing the bonding material may be performed in two steps, a heating step, and a quick cooling step. One type of post-processing step may be chilling the bonding material 360 after pressing the bonding material 360 onto the embossment 808. Chilling also helps to prevent the edge problems. The bonding material may be chilled after embossment to between 18 and 25° C. Combined pre- and post-processing improves the physical characteristics of the bonding material and increases the likelihood of bubble prevention during lamination.

Once the bonding material has been embossed, the will need to know the orientation of the glass and bonding material so that the mating pattern formed in the bonding material will properly align, angularly and axially, with the device substrate 303. An automated vision system may match the bonding material 360 with the back glass substrate 361 prior to lamination.

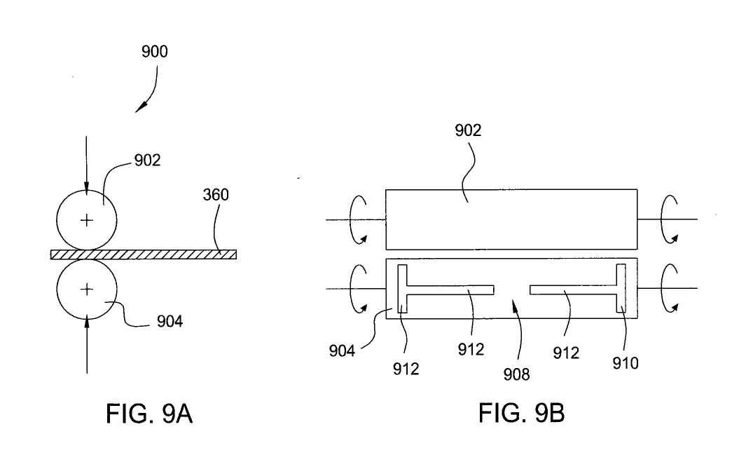

FIGS. 9A-9B illustrate a set of rollers 900 having an embossment 908 according to one embodiment described herein. In this method of preparing a pre-patterned bonding material for a solar cell assembly, the bonding material 360 passes between at least two rollers, such as upper roller 902 and lower roller 904. At least one roller, such as lower roller 904, has an embossment 908, where at least a portion of the embossment 908 corresponds to a topography 710 of an exposed surface of a device substrate 303.

The embossment 908 may have the same pattern as the busses 355, 356. For example, the embossment 908 includes a side-buss surface projection 910 corresponding in length and thickness to the side-buss 355. A cross-buss surface projection 912 roughly mirrors the length and thickness of the cross-buss 356. A central hole 915 corresponds to a hole in the back substrate glass 361 and bonding material 360 necessary to electrically connect the junction box with the cross-buss 356, as previously described in step 138. The bonding material may be pre-cut into sheets that match the size of the device substrate 303. Pre-cutting the bonding material may take place at material perpetration module 232A discussed above in connection with process steps 131-136.

The bonding material 360 is heated and passed through the rollers 900 to form a mating pattern. The heating of the bonding material may include locally heating the rollers or a portion of the bonding material corresponding to the topography of the exposed surface. In one embodiment, only the embossment 908 is heated to create the localized heating of the bonding material 360 along the areas of the mating pattern. The localized heating may heat portions of the bonding material to a temperature between 30 and 95° C. for imprinting the pattern on the bonding material.

Similar pre- and post-pattern processing steps may be performed to prepare the bonding material for lamination. In one embodiment, the bonding material 360 may continuously roll off a reel of the bonding material and pass between the rollers 900. In this method, the bonding material would not need to be pre-cut, but could come of another reel and cut to size just before placement over the exposed surface of the cross- and side-busses and the back contact layer prior to lamination. A separate embossment table or work surface would be unnecessary.

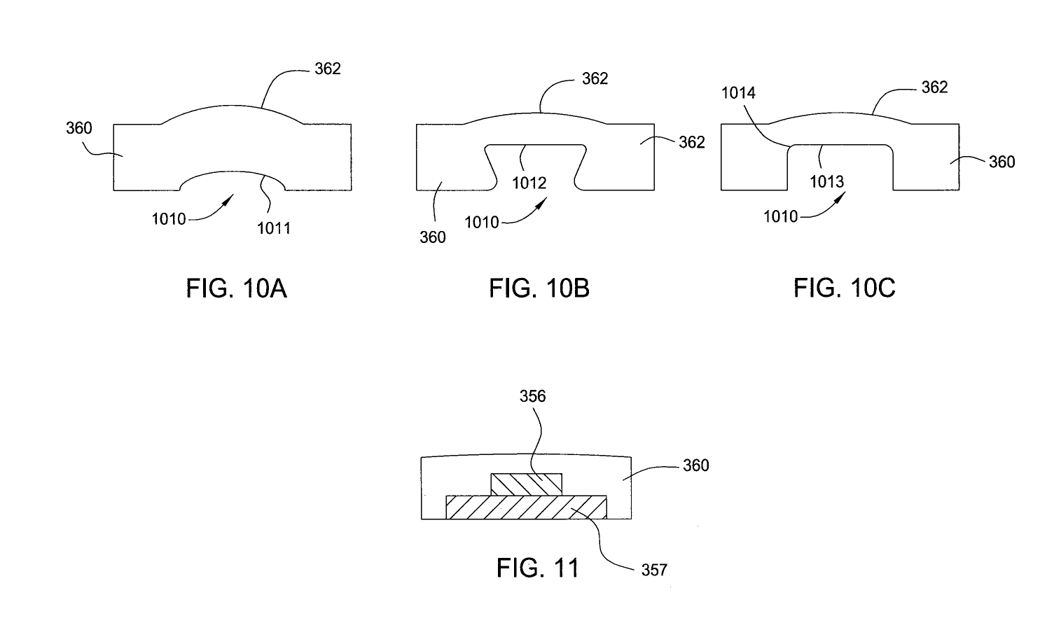

FIGS. 10A-10B illustrate a mating pattern 1010 formed on a bonding material 360 according to embodiments described herein. Various cross-sections of the mating pattern may be formed from the embossment. FIG. 10A shows a shallow groove 1011 may be formed in the bonding material 360. Embossing the bonding material may also form a bump or protrusion 362 that may be necessary to flatten some prior to lamination. FIG. 10B shows a groove 912 having sidewalls angling toward the center to help prevent bubbles and better match the profile of the busses. FIG. 10C shows a groove 1013 that is deeper and has filleted corners for a smoother transition between the bonding material 360 and the busses. However, an oversized pattern compared to the topography of the surface may otherwise create bubbles.

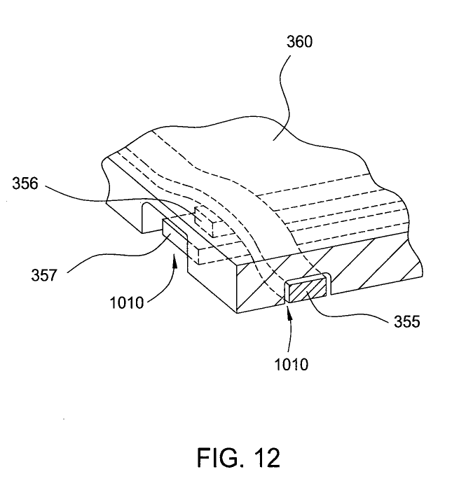

FIG. 11 is a cross-sectional view of a bonding material 360 placed over the cross-buss 356 and isolation tape 357. By matching the topography of the exposed surface, including the busses, the prevention of bubbles during lamination is increased. FIG. 12 is a partial cross-sectional isometric view of the pre-patterned bonding material 360 over the internal electrical connections prior to lamination. The large variation in step topography of the exposed surface at the overlap area of the side-buss 355 and cross-buss 356 may create the greatest concern for bubble formation. As illustrated, a sheet of bonding material 360 that has been pre-patterned with a mating pattern to match the topography of the surface, overlays and covers the transition corners between the busses and the isolation tape, thereby reducing the bubble formation during lamination.

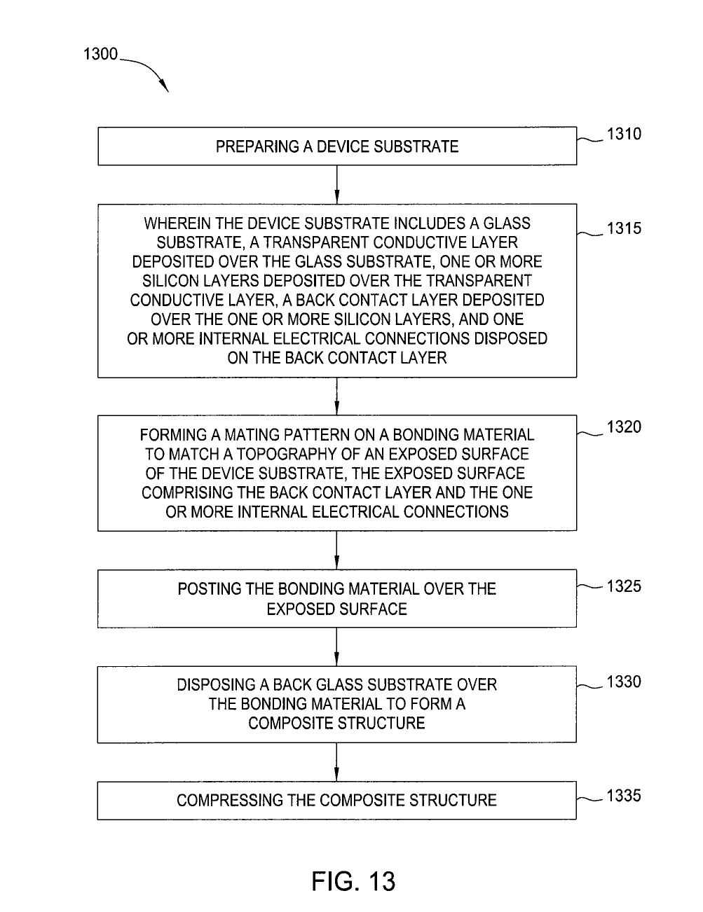

FIG. 13 schematically illustrates a method 1300 of forming a composite solar cell structure according to one embodiment described herein. The method 1300 includes preparing a device substrate, box 1310, wherein the device substrate includes a glass substrate, a transparent conductive layer deposited over the glass substrate, one or more silicon layers deposited over the transparent conductive layer, a back contact layer deposited over the one or more silicon layers, and one or more internal electrical connections disposed on the back contact layer, box 1315. The method 1300 also includes forming a mating pattern on a bonding material to match a topography of an exposed surface of the device substrate, the exposed surface comprising the back contact layer and the one or more internal electrical connections, box 1320. The method also includes positioning the bonding material over the exposed surface, box 1325, disposing a back glass substrate over the bonding material to form a composite structure, box 1330, and compressing the composite structure, box 1335.

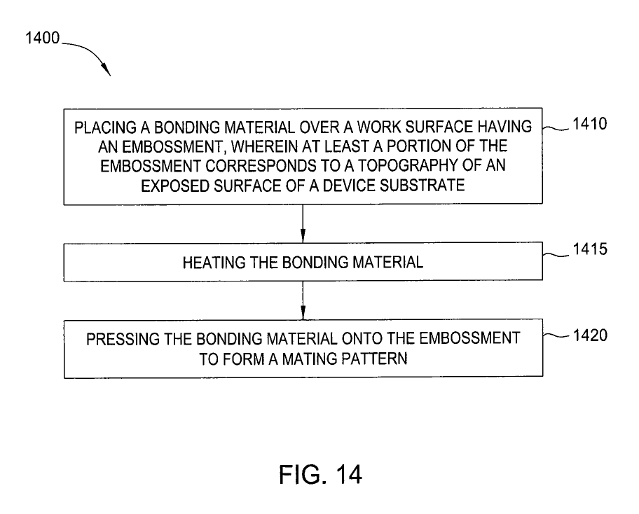

FIG. 14 schematically illustrates a method 1400 of preparing a pre-patterned bonding material for a solar cell assembly according to one embodiment described herein. The method includes placing a bonding material over a work surface having an embossment, wherein at least a portion of the embossment corresponds to a topography of an exposed surface of a device substrate, box 1410, heating the bonding material, box 1415, and pressing the bonding material onto the embossment to form a mating pattern, box 1420.

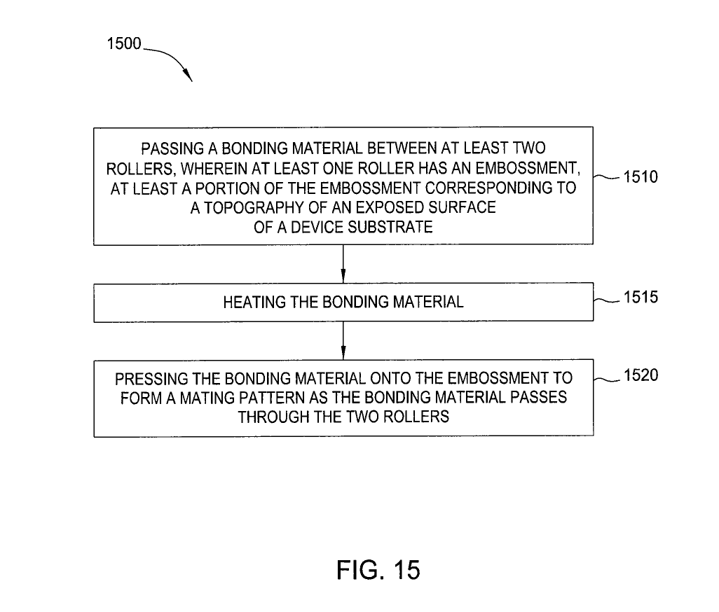

FIG. 15 schematically illustrates a method 1500 of preparing a pre-patterned bonding material for a solar cell assembly according to one embodiment described herein. The method includes passing a bonding material between at least two rollers, wherein at least one roller has an embossment, at least a portion of the embossment corresponding to a topography of an exposed surface of a device substrate, box 1510, heating the bonding material, box 1515, and pressing the bonding material onto the embossment to form a mating pattern as the bonding material passes through the two rollers, box 1520.

The above described embodiments can be readily implemented along an automated solar cell production line and help prevent bubble formation during lamination of large area solar cell substrates. Prevention of bubble formation improves efficiency due to decreased exposure to environmental conditions, such as heat and humidity. Large-sized solar cells present a challenge due to the locally stepped topography from cross- and side-busses, which embodiments of the invention help overcome.

While the foregoing is directed to embodiments of the present invention, other and further embodiments of the invention may be devised without departing from the basic scope thereof, and the scope thereof is determined by the claims that follow.

1. A method of forming a composite solar cell structure, comprising:
preparing a device substrate, wherein the device substrate comprises:
a glass substrate;
a transparent conductive layer deposited over the glass substrate;
one or more silicon layers deposited over the transparent conductive layer;
a back contact layer deposited over the one or more silicon layers; and
one or more internal electrical connections disposed on the back contact layer;
forming a mating pattern on a bonding material to match a topography of an exposed surface of the device substrate, the exposed surface comprising the back contact layer and the one or more internal electrical connections;
positioning the bonding material over the exposed surface;
disposing a back glass substrate over the bonding material to form a composite structure; and
compressing the composite structure.

2. The method of claim 1, wherein forming a mating pattern on a bonding material further comprises:
embossing the mating pattern on a bonding material by a method comprising:
placing a bonding material over a work surface having an embossment, wherein at least a portion of the embossment corresponds to a topography of an exposed surface of a device substrate;
heating the bonding material; and
pressing the bonding material onto the embossment to form a mating pattern.

3. The method of claim 1, wherein forming a mating pattern on a bonding material further comprises:
embossing the mating pattern on a bonding material by a method comprising:
passing a bonding material between at least two rollers, wherein at least one roller has an embossment, at least a portion of the embossment corresponding to a topography of an exposed surface of a device substrate;
heating the bonding material; and
pressing the bonding material onto the embossment to form a mating pattern as the bonding material passes through the two rollers.

4. The method of claim 3, further comprising:
aligning the mating pattern with the topography of the exposed surface; and
aligning the back glass substrate with the bonding material.

5. The method of claim 1, wherein the bonding material is polyvinyl butyral or ethylene vinyl acetate.

6. The method of claim 2, wherein the embossment is heated to provide localized heating of the bonding material corresponding to the topography of the exposed surface.

7. The method of claim 3, wherein the embossment is heated to provide localized heating of the bonding material corresponding to the topography of the exposed surface.

8. The method of claim 1, further comprising:
relaxing the bonding material before forming a mating pattern; and
chilling the bonding material before positioning the bonding material over the exposed surface.

9. A method of preparing a pre-patterned bonding material for a solar cell assembly, comprising:
placing a bonding material over a work surface having an embossment, wherein at least a portion of the embossment corresponds to a topography of an exposed surface of a device substrate;
heating the bonding material; and
pressing the bonding material onto the embossment to form a mating pattern.

10. The method of claim 9, wherein heating the bonding material comprises locally heating a portion of the bonding material corresponding to the topography of the exposed surface.

11. The method of claim 10, wherein only the embossment is heated.

12. The method of claim 9, wherein heating the bonding material is performed at a temperature between 30 and 95° C.

13. The method of claim 9, further comprising:
relaxing the bonding material before placing the bonding material over the work surface; and
chilling the bonding material after pressing the bonding material onto the embossment.

14. The method of claim 13, wherein the chilling comprises:
chilling the bonding material to between 18 and 25° C.

15. The method of claim 9, wherein the bonding material is polyvinyl butyral or ethylene vinyl acetate.

16. The method of claim 9, wherein the bonding material comprises pre-cut sheets.

17. A method of preparing a pre-patterned bonding material for a solar cell assembly, comprising:
passing a bonding material between at least two rollers, wherein at least one roller has an embossment, at least a portion of the embossment corresponding to a topography of an exposed surface of a device substrate;
heating the bonding material; and
pressing the bonding material onto the embossment to form a mating pattern as the bonding material passes through the two rollers.

18. The method of claim 17, wherein the embossment is heated to provide localized heating of the bonding material corresponding to the topography of the exposed surface.

19. The method of claim 17, wherein the heating the bonding material is performed at a temperature between 30 and 95° C.

20. The method of claim 17, further comprising:
relaxing the bonding material before passing the bonding material between at least two rollers; and
chilling the bonding material after pressing the bonding material onto the embossment.

21. The method of claim 20, wherein the chilling comprises:
chilling the bonding material to between 18 and 25° C.

22. The method of claim 17, wherein the bonding material is polyvinyl butyral or ethylene vinyl acetate.

23. The method of claim 17, further comprising:
continuously passing a roll of the bonding material between the at least two rollers; and
cutting the roll of embossed bonding material to sheets for placing over an exposed area of a substrate device.
